(19) United States
(12) Patent Application Publication
(10) Pub. No.: US 2026/0024731 A1
(43) Pub. Date: Jan. 22, 2026

(54) SUBSTRATE PROCESSING APPARATUS AND METHOD OF ADJUSTING HEIGHT OF RING MEMBER

(71) Applicant: SEMES CO., LTD., Cheonan-si (KR)

(72) Inventors: Sung Hyuk JUNG, Cheonan-si (KR); Ho Hun LEE, Cheonan-si (KR); Tae Dong PARK, Cheonan-si (KR)

(73) Assignee: SEMES CO., LTD., Cheonan-si (KR)

(21) Appl. No.: 19/264,985

(22) Filed: Jul. 10, 2025

(30) Foreign Application Priority Data
Jul. 18, 2024 (KR) 10-2024-0094969

(51) Int. Cl. H01J 37/32; H01L 21/687

(52) U.S. Cl. CPC H01J 37/32642; H01L 21/68735; H01L 21/68742; H01J 2237/24578; H01J 2237/3341

(57) ABSTRACT

Disclosed is a substrate processing apparatus capable of checking an etch amount of a ring member without opening a chamber. The substrate processing apparatus using plasma includes a process chamber defining a process space, a chuck located in the process space to support a substrate from below, a ring member located around the chuck, a ring lifting device configured to raise and lower the ring member, and a controller configured to measure an etch amount of the ring member and to adjust the height of the ring member based on the etch amount using the ring lifting device. A substrate-type sensor device including a laser light source and a camera is located in the process space. The laser light source irradiates the chuck and the ring member. The camera captures an image including the chuck and the ring member and transmits the image to the controller for etch amount measurement.

### CROSS-REFERENCE TO THE RELATED APPLICATION

The present application claims priority to and the benefit of Korean Patent Application No. 10-2024-0094969, filed on Jul. 18, 2024, in the Korean Intellectual Property Office, the entire disclosure of which is incorporated herein by reference.

### BACKGROUND

### 1. Field

The present disclosure relates to a substrate processing apparatus using plasma and a method of adjusting the height of a ring member in the substrate processing apparatus.

### 2. Description of the Related Art

A semiconductor (or display) manufacturing process is a process for manufacturing a semiconductor device on a substrate (e.g., a wafer), and includes, for example, exposure, deposition, etching, ion implantation, and cleaning. In order to perform each manufacturing process, semiconductor manufacturing equipment that performs each process is provided in a clean room of a semiconductor manufacturing plant, and each process is performed on a substrate loaded in the semiconductor manufacturing equipment.

Processes using plasma, for example, etching and deposition, are widely used in the semiconductor manufacturing process. A substrate processing apparatus that processes a substrate using plasma includes a process chamber maintained in a vacuum state, a support chuck that supports a substrate in the process chamber, and a focus ring that surrounds the outer circumference of the substrate seated on the support chuck. The focus ring is mounted to achieve highly uniform distribution of plasma on the surface of the substrate, and is etched together with the substrate by the plasma. Thus, as the etching process is performed on a plurality of substrates, the focus ring is also etched repeatedly, so the shape of the focus ring gradually changes. As the shape of the focus ring changes, the incident direction of ions and/or radicals on the substrate varies, resulting in a change in the etching characteristics of the substrate. Accordingly, the focus ring needs to be replaced when etching has been performed on more than a predetermined number of substrates or when the change in the shape of the focus ring exceeds a set limit.

In order to replace the focus ring at an appropriate time, it is important to check the degree of wear (e.g., etch amount) of the focus ring. Conventionally, an operator manually opens the process chamber or brings a measuring instrument, such as a measuring jig, into direct contact with the focus ring to check the degree of wear of the focus ring. However, in the former case, it may be difficult to properly check the degree of wear of the focus ring when needed, and in the latter case, the focus ring may be damaged, for example, scratched, due to physical contact with the measuring instrument.

### SUMMARY

The present disclosure provides a substrate processing apparatus capable of checking an etch amount of a ring member without opening a chamber and a method of adjusting the height of the ring member.

A substrate processing apparatus using plasma according to the present disclosure includes a process chamber defining a process space for a substrate, a chuck located in the process space and configured to support the substrate from below, a ring member located around an edge of the chuck, a ring lifting device configured to raise and lower the ring member, and a controller configured to measure an etch amount of the ring member and to adjust the height of the ring member based on the etch amount using the ring lifting device. A substrate-type sensor device having a shape corresponding to the substrate and including a laser light source and a camera is located in the process space. The laser light source emits a laser beam to the chuck and the ring member. The camera captures an image including the chuck and the ring member and transmits the image to the controller. The controller measures the etch amount of the ring member based on the image.

In the embodiment of the present disclosure, the substrate-type sensor device may be moved into the process space while being supported by a robot hand of a transfer robot. With the substrate-type sensor device being supported by the robot hand and spaced apart from the chuck, the laser light source may direct the laser beam toward the chuck and the ring member, and the camera may capture the image.

In the embodiment of the present disclosure, the substrate-type sensor device may transmit the image to the controller via a wireless communication module.

In the embodiment of the present disclosure, the controller may detect a chuck reference line corresponding to a surface of the chuck in the image, may detect a ring reference line corresponding to an upper surface of the ring member, and may compare the position of the chuck reference line with the position of the ring reference line to measure the etch amount of the ring member.

In the embodiment of the present disclosure, the controller may compare a first image captured at a first time point with a second image captured after a predetermined time period has elapsed from the first time point or after a process has been performed a predetermined number of times to measure the etch amount of the ring member.

In the embodiment of the present disclosure, the controller may detect a first chuck reference line corresponding to a surface of the chuck and a first ring reference line corresponding to an upper surface of the ring member in the first image and may measure a first distance between the first chuck reference line and the first ring reference line in the first image.

In the embodiment of the present disclosure, the controller may detect a second chuck reference line corresponding to the surface of the chuck and a second ring reference line corresponding to the upper surface of the ring member in the second image and may measure a second distance between the second chuck reference line and the second ring reference line in the second image.

In the embodiment of the present disclosure, the controller may measure the etch amount of the ring member based on a difference between the first distance and the second distance.

In the embodiment of the present disclosure, the controller may control the ring lifting device to raise the ring member when the etch amount of the ring member exceeds a reference value.

In the embodiment of the present disclosure, the controller may control the ring lifting device to raise the ring member by a height corresponding to the etch amount of the ring member.

A method of adjusting the height of a ring member located around an edge of a chuck supporting a substrate in a substrate processing apparatus using plasma according to the present disclosure includes placing a substrate-type sensor device, having a shape corresponding to the substrate and including a laser light source and a camera, in a process space in a process chamber, emitting, by the laser light source, a laser beam to the chuck and the ring member, capturing, by the camera, an image including the chuck and the ring member, measuring an etch amount of the ring member based on the image, and adjusting the height of the ring member based on the etch amount of the ring member.

A substrate processing apparatus using plasma according to the present disclosure includes a process chamber defining a process space for a substrate, a transfer robot including a robot hand configured to transfer the substrate to the process space, a chuck located in the process space and configured to support the substrate from below, a ring member located around an edge of the chuck, a ring lifting device configured to raise and lower the ring member, and a controller configured to measure an etch amount of the ring member and to adjust the height of the ring member based on the etch amount using the ring lifting device. A substrate-type sensor device having a shape corresponding to the substrate and including a laser light source and a camera is located in the process space while being supported by the robot hand. With the substrate-type sensor device being supported by the robot hand and spaced apart from the chuck, the laser light source emits a laser beam to the chuck and the ring member. The camera captures an image including the chuck and the ring member and transmits the image to the controller. The controller compares a first image captured at a first time point with a second image captured after a predetermined time period has elapsed from the first time point or after a process has been performed a predetermined number of times to measure the etch amount of the ring member.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 is a view schematically showing the structure of a substrate processing apparatus according to the present disclosure;

FIG. 2 is a view showing the internal structure of a process chamber in the substrate processing apparatus in FIG. 1;

FIG. 3 is a view showing the internal structures of a transfer chamber and the process chamber in the substrate processing apparatus in FIG. 2;

FIG. 4 is a view showing a state in which a substrate-type sensor device has entered the process chamber in the substrate processing apparatus in FIG. 2;

FIG. 5 shows examples of images captured by a camera of the substrate-type sensor device; and

FIG. 6 is a flowchart showing a method of adjusting the height of a ring member in the substrate processing apparatus according to the present disclosure.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is said to be “connected”, “coupled”, or “joined” to another constituent element, the constituent element and the other constituent element may be “directly connected”, “directly coupled”, or “directly joined” to each other, or may be “indirectly connected”, “indirectly coupled”, or “indirectly joined” to each other with one or more intervening elements interposed therebetween. In addition, throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

A substrate processing apparatus as semiconductor manufacturing equipment of the embodiment may be used to perform a process on a substrate such as a semiconductor wafer or a flat display panel. In particular, the substrate processing apparatus 1000 of the embodiment is an apparatus that performs an etching or deposition process on a substrate using plasma.

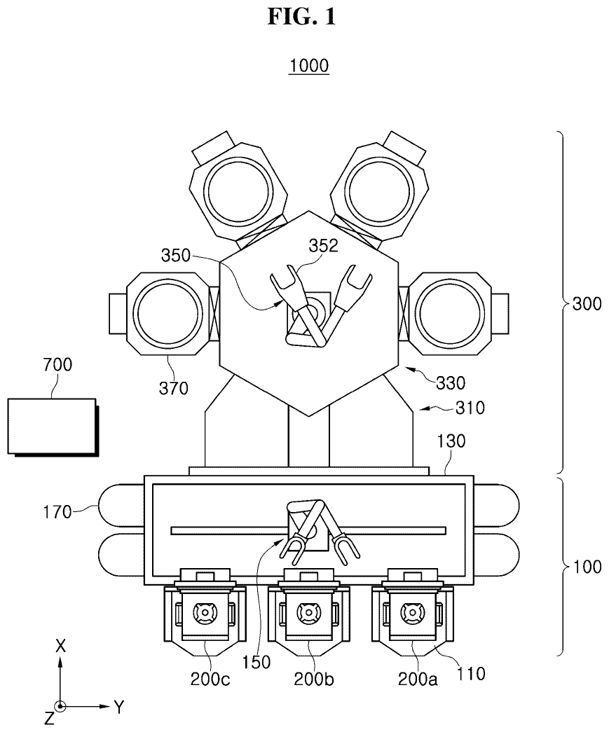

FIG. 1 is a view schematically showing the structure of the substrate processing apparatus 1000 according to the present disclosure. Referring to FIG. 1, the substrate processing apparatus 1000 according to an embodiment of the present disclosure may include an index unit 100, a processing unit 300, and a controller 700. The index unit 100 and the processing unit 300 may be arranged in a first direction X when viewed from above. Hereinafter, when viewed from above, a direction that is perpendicular to the first direction X is defined as a second direction Y. In addition, a direction that is perpendicular to the first direction X and the second direction Y is defined as a third direction Z. Here, the third direction Z may be a direction that is perpendicular to the ground.

The index unit 100 may include a load port 110, an index chamber 130, a first transfer robot 150, and a side buffer 170.

Containers 200a, 200b, and 200c may be seated on the load port 110. Various types of containers 200a, 200b, and 200c may be seated on the load port 110. For example, various types of containers 200a, 200b, and 200c storing different items may be seated on the load port 110. For example, among the containers 200a, 200b, and 200c, the first container 200a may store a ring member R that is to be transferred to a process chamber 370, which will be described later, and/or a carrier used to transfer the ring member R. In addition, the second container 200b may store a substrate-type sensor device 800, which will be described later. In addition, the third container 200c may store a substrate W (e.g., a wafer), which is a workpiece to be processed in the process chamber 370.

However, the present disclosure is not limited thereto, and the first container 200a may store at least one of the ring member R, the carrier, the substrate-type sensor device 800, or the substrate W. Similarly, each of the second container 200b and the third container 200c may also store at least one of the ring member R, the carrier, the substrate-type sensor device 800, or the substrate W.

The containers 200a, 200b, and 200c may be transferred to and loaded on the load port 110 or may be unloaded and transferred from the load port 110 by a container transfer device. The container transfer device may be an overhead hoist transport (OHT), but the present disclosure is not limited thereto. The containers 200a, 200b, and 200c may be transferred by various other transfer devices. Alternatively, an operator may manually load or unload the containers 200a, 200b, and 200c on or from the load port 110.

The substrate processing apparatus 1000 according to the embodiment of the present disclosure may transfer the substrate-type sensor device 800 stored in the second container 200b to the process chamber 370 using a first transfer robot 150 and a second transfer robot 350, which will be described later. In addition, the substrate processing apparatus 1000 may transfer the substrate-type sensor device 800 having performed measurement in the process chamber 370 to the second container 200b using the first transfer robot 150 and the second transfer robot 350, which will be described later.

The index chamber 130 may be provided between the load port 110 and the processing unit 300. That is, the load port 110 may be connected to the index chamber 130. The index chamber 130 may be maintained at atmospheric pressure. The side buffer 170, which is a storage unit, may be mounted on one side of the index chamber 130. In addition, the first transfer robot 150 may be provided in the index chamber 130. The first transfer robot 150 may transfer the substrate W, the substrate-type sensor device 800, and the ring member R between the containers 200a, 200b, and 200c seated on the load port 110, a load lock chamber 310 to be described later, and the side buffer 170. That is, the first transfer robot 150 may unload the substrate-type sensor device 800 from the second container 200b.

The processing unit 300 may include a load lock chamber 310, a transfer chamber 330, a second transfer robot 350, and a process chamber 370.

The load lock chamber 310 may be disposed between the transfer chamber 330 and the index chamber 130. That is, the load lock chamber 310 may be connected to the index chamber 130 and the transfer chamber 330. The load lock chamber 310 provides a space in which the substrate W and/or the ring member R is temporarily stored. The load lock chamber 310 may be provided with a vacuum pump (not shown) and a valve (not shown) to switch the internal atmosphere thereof between atmospheric pressure and vacuum. Because the internal atmosphere of the transfer chamber 330, which will be described later, is maintained in a vacuum, the internal atmosphere of the load lock chamber 310 may be switched between atmospheric pressure and vacuum in order to transfer the substrate W and the ring member R between the transfer chamber 330 and the index chamber 130.

The transfer chamber 330 may be disposed between the load lock chamber 310 and the process chamber 370. The internal atmosphere of the transfer chamber 330 may be maintained in a vacuum, as described above. In addition, the second transfer robot 350 may be provided in the transfer chamber 330. The second transfer robot 350 may transfer the substrate W and the ring member R between the load lock chamber 310 and the process chamber 370. The second transfer robot 350 may transfer the substrate W or the ring member R between the process space in the process chamber 370 and the transfer chamber 330. The second transfer robot 350 includes a robot hand 352. The second transfer robot 350 may be configured to allow the robot hand 352 to move in the first direction X, the second direction Y, or the third direction Z. In addition, the second transfer robot 350 may be configured to allow the robot hand 352 to rotate about an axis extending in the third direction Z.

At least one process chamber 370 may be connected to the transfer chamber 330. The process chamber 370 may receive the substrate W from the second transfer robot 350 provided in the transfer chamber 330, and may perform a predetermined process. The process chamber 370 may be a chamber that performs a predetermined process on the substrate W. The process chamber 370 may be a liquid processing chamber that supplies a processing liquid to the substrate W to process the substrate W. Alternatively, the process chamber 370 may be a plasma chamber that processes the substrate W using plasma. Alternatively, some of the process chambers 370 may be liquid processing chambers that supply a processing liquid to the substrate W to process the substrate W, and the others thereof may be plasma chambers that process the substrate W using plasma. However, the present disclosure is not limited thereto, and the process chamber 370 may be configured to perform various other known substrate processing processes. Furthermore, if the process chamber 370 is a plasma chamber that processes the substrate W using plasma, the plasma chamber may be a chamber that performs an etching or ashing process of removing a thin film on the substrate W using plasma. However, the present disclosure is not limited thereto, and the process chamber 370 may be configured to perform various other known plasma processing processes. The detailed structure of the process chamber 370 will be described later.

In addition, although FIG. 1 illustrates an example in which the transfer chamber 330, when viewed from above, has a substantially hexagonal shape and four process chambers 370 are connected to the transfer chamber 330, the present disclosure is not limited thereto. For example, the shape of the transfer chamber 330 and the number of process chambers 370 may vary depending on operational requirements or the number of substrates to be processed.

The controller 700 may control the substrate processing apparatus 1000. The controller 700 may control the index unit 100 and the processing unit 300. The controller 700 may control the first transfer robot 150 and the second transfer robot 350. The controller 700 may control the substrate processing apparatus provided in the process chamber 370 and the transfer chamber 330 to process the substrate W using plasma in the process chamber 370.

Furthermore, the controller 700 may include a process controller implemented as a microprocessor (computer) that controls the substrate processing apparatus 1000, a user interface including a keyboard that enables an operator to input commands for management of the substrate processing apparatus 1000 or a display that visually displays the operational state of the substrate processing apparatus 1000, and a memory unit storing a control program for execution of a process in the substrate processing apparatus 1000 under the control of the process controller or a program that enables the components to perform a process based on various data and processing conditions, i.e., a process recipe. Furthermore, the user interface and the memory unit may be connected to the process controller. The process recipe may be stored in a memory medium of the memory unit. The memory medium may be a hard disk, a transportable disk such as a compact disc read only memory (CD-ROM) or digital versatile disc (DVD), or a semiconductor memory such as flash memory. In the present disclosure, the controller 700 measures an etch amount of the ring member R, which will be described later, and adjusts the height of the ring member R using a ring lifting device 560 based on the etch amount.

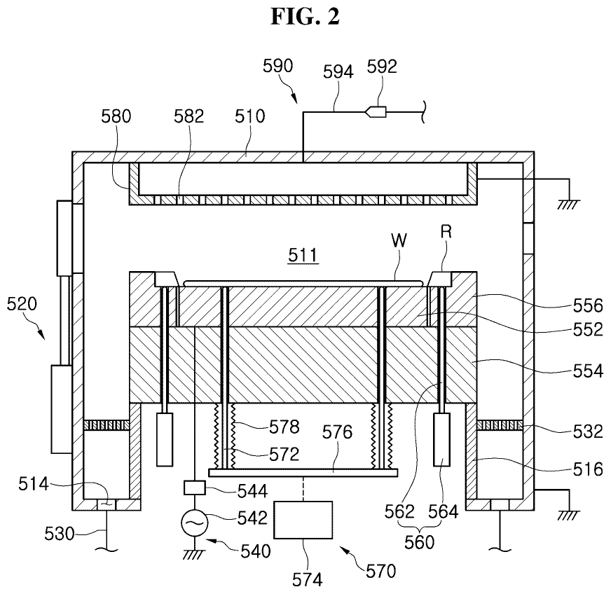

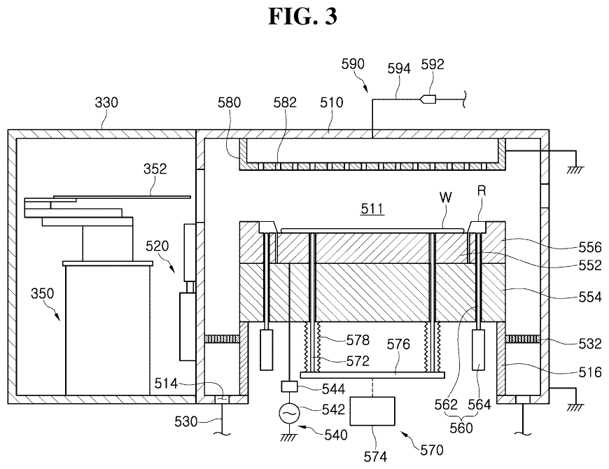

FIGS. 2 and 3 are views showing the substrate processing apparatus according to the present disclosure. FIG. 2 shows the substrate processing apparatus provided in the process chamber 370. FIG. 3 shows the substrate processing apparatus provided in the transfer chamber 330 and the process chamber 370. The substrate processing apparatus may transmit plasma to the substrate W to process the substrate W.

The substrate processing apparatus may include a process chamber 510, a gate valve 520, an exhaust line 530, a power supply unit 540, a support unit 550, a ring lifting device 560, a substrate lifting module 570, a baffle plate 580, and a gas supply unit 590.

The process chamber 510 may define a process space 511 for the substrate W. The process chamber 510 may be grounded. The process chamber 510 may provide a process space 511 in which the substrate W is processed. The process space 511 in the process chamber 510 may be maintained in a substantially vacuum state during the processing of the substrate W. A loading/unloading port 512, through which the substrate W or the ring member R is loaded and unloaded, may be formed in one side of the process chamber 510. The gate valve 520 may selectively open and close the loading/unloading port 512.

An exhaust hole 514 may be formed in the bottom surface of the process chamber 510. The exhaust line 530 may be connected to the exhaust hole 514. The exhaust line 530 may discharge a process gas supplied to the process space in the process chamber 510 and a process byproduct to the outside of the process chamber 510 through the exhaust hole 514. In addition, an exhaust plate 532 may be provided above the exhaust hole 514 in order to more uniformly discharge gas from the process space. The exhaust plate 532 may have a substantially ring-like shape when viewed from above. In addition, at least one exhaust hole may be formed in the exhaust plate 532. The operator may select an exhaust plate 532 capable of uniformly discharging gas from the process space from among a plurality of exhaust plates with various shapes and sizes, and may mount the selected exhaust plate 532 above the exhaust hole 514.

In addition, the process chamber 510 may further include a support member 516. The support member 516 may support at least a portion of a base part of the support unit 550, which will be described later. For example, the support member 516 may be configured to support a lower side of an insulating plate 554 of the support unit 550.

The power supply unit 540 may generate radio-frequency (RF) power to excite a process gas supplied from the gas supply unit 590, which will be described later, into a plasma state. The power supply unit 540 may include a power supply 542 and a matcher 544. The power supply 542 and the matcher 544 may be mounted on a power transmission line. Furthermore, the power transmission line may be connected to a chuck 552.

The support unit 550 may support the substrate W in the process space in the process chamber 510. The support unit 550 may include a chuck 552, an insulating plate 554, a quartz ring 556.

The chuck 552 is located in the process space 511 to support the substrate W from below. The chuck 552 may have a support surface that supports the substrate W. The chuck 552 may support the substrate W and may chuck the supported substrate W. For example, an electrostatic plate (not shown) may be provided inside the chuck 552 to chuck the substrate W with electrostatic force. For example, the chuck 552 may be an electrostatic chuck (ESC). However, the present disclosure is not limited thereto, and the chuck 552 may also be configured to chuck the substrate W through a vacuum adsorption method.

The insulating plate 554 may be disc-shaped when viewed from above. The chuck 552 described above and the quartz ring 556 to be described later may be disposed on the insulating plate 554. The insulating plate 554 may be made of a dielectric material. For example, the insulating plate 554 may be made of a material including ceramic.

The quartz ring 556 may be made of a material including quartz. The quartz ring 556 may have a ring-like shape when viewed from above. The quartz ring 556 may have a shape that surrounds the chuck 552 when viewed from above. The quartz ring 556 may be formed in a shape that surrounds the substrate W supported by the chuck 552 when viewed from above.

In addition, the quartz ring 556 may have a stepped shape in which the upper surface of the inner side thereof and the upper surface of the outer side thereof have different heights. For example, the upper surface of the inner side of the quartz ring 556 may have a smaller height than the upper surface of the outer side thereof. In addition, the ring member R (e.g., a focus ring) may be disposed on the upper surface of the inner side of the quartz ring 556. The ring member R is located around the edge of the chuck 552.

A sealing member may be provided between the insulating plate 554 and the chuck 552 in order to prevent the occurrence of arcing in the gap between pin holes formed in the insulating plate 554 and the chuck 552.

A ring lifting device 560 may raise and lower the ring member R disposed on the upper surface of the inner side of the quartz ring 556. The ring lifting device 560 may include a ring lifting pin 562 and a ring lifting pin lifter 564. The ring lifting pin 562 may be moved up and down along a pin hole formed in the insulating plate 554 and/or the quartz ring 556. Furthermore, the ring lifting pin 562 may be moved up and down by the ring lifting pin lifter 564. That is, the ring lifting pin lifter 564 may raise and lower the ring lifting pin 562. The ring lifting pin lifter 564 may be a cylinder using pneumatic or hydraulic pressure or may be a motor.

The substrate lifting module 570 may raise and lower the substrate W placed on the chuck 552. The substrate lifting module 570 may include a substrate lifting pin 572, a substrate lifting pin lifter 574, a lifting plate 576, and a bellows 578. The substrate lifting pin 572 may be moved up and down along the pin hole formed in the insulating plate 554 and/or the chuck 552. The substrate lifting pin 572 may be coupled to the lifting plate 576, which receives power from the substrate lifting pin lifter 574, and may be moved up and down by lifting of the lifting plate 576. In addition, the bellows 578 may be mounted on a connection portion between the lifting plate 576 and the substrate lifting pin 572 in order to secure airtightness.

The baffle plate 580 may be provided above the support unit 550. The baffle plate 580 may be made of an electrode material. At least one baffle hole 582 may be formed in the baffle plate 580. As one example, the baffle hole 582 may be provided in plural, and the plurality of baffle holes 582 may be evenly formed over the entire area of the baffle plate 580 when viewed from above. The baffle plate 580 allows a process gas supplied from the gas supply unit 590, which will be described later, to be uniformly delivered to the substrate W.

The gas supply unit 590 may supply a process gas to the process space in the process chamber 510. The process gas may be a gas that is excited into a plasma state by the power supply unit 540 described above. The gas supply unit 590 may include a gas source 592 and a gas supply line 594. One end of the gas supply line 594 may be connected to the gas source 592, and the other end thereof may be connected to an upper portion of the process chamber 510. Accordingly, the process gas delivered by the gas source 592 may be supplied to an upper region of the baffle plate 580 through the gas supply line 594. The process gas supplied to the upper region of the baffle plate 580 may be introduced into the process space in the process chamber 510 through the baffle hole 582.

As shown in FIG. 3, the transfer chamber 330 is mounted adjacent to the process chamber 510. The second transfer robot 350, which is a transfer robot for transporting the substrate W, is provided in the transfer chamber 330. The second transfer robot 350 includes a robot hand 352 that supports the substrate W. The robot hand 352 enters the process space 511 in the process chamber 510 while supporting the substrate W. The substrate lifting pin 572 of the substrate lifting module 570 is raised to support the substrate W, and when the robot hand 352 is moved out of the process space 511, the substrate lifting pin 572 is lowered, so the substrate W is supported by the chuck 552.

Hereinafter, a method of adjusting the height of the ring member R by measuring the etch amount of the ring member R will be described. In the substrate processing apparatus, as the substrate processing time and the number of processing cycles using plasma increase, the ring member R is etched, whereby plasma may be non-uniformly distributed. To maintain a uniform plasma distribution, the ring member R is raised by the etch amount thereof.

Generally, a method of raising the ring member R by predicting the etch amount of the ring member R according to the processing time, i.e., a method of raising the ring member R by a height corresponding to the processing time, is used. However, the method of raising the ring member R by a height corresponding to the processing time is based on an estimate rather than actual data, making it highly likely to be inaccurate.

Therefore, the present disclosure proposes a substrate processing apparatus designed to calculate the etch amount of the ring member R using the substrate-type sensor device 800, which is configured to check the internal state of the process chamber 510 without opening the process chamber 510, thereby enabling more reliable and accurate adjustment of the height of the ring member R.

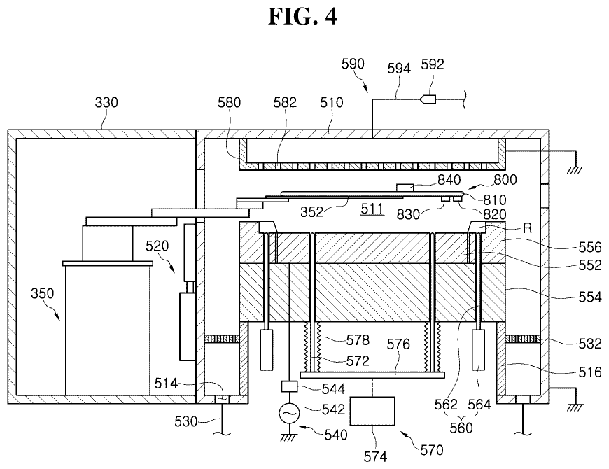

FIG. 4 is a view showing a state in which the substrate-type sensor device 800 has entered the process chamber in the substrate processing apparatus according to the present disclosure. The substrate-type sensor device 800 has a shape corresponding to the substrate W. The substrate-type sensor device 800 may be disc-shaped, like a 300 mm wafer.

The substrate-type sensor device 800 may include a circular plate 810, a laser light source 820, a camera 830, and a wireless communication module 840. The circular plate 810 may have a shape corresponding to the substrate W. The laser light source 820, the camera 830, and the wireless communication module 840 may be mounted on the upper or lower surface of the circular plate 810. In addition, a power supply device (e.g., a battery) that supplies power to the laser light source 820, the camera 830, and the wireless communication module 840 may be mounted on the circular plate 810. As shown in FIG. 4, the laser light source 820 and the camera 830 may be mounted on the lower surface of the circular plate 810, and the wireless communication module 840 may be mounted on the upper surface of the circular plate 810. The laser light source 820, the camera 830, and the wireless communication module 840 may be electrically connected to one another.

The laser light source 820 may emit a laser beam in a predetermined direction. The laser light source 820 may direct the laser beam toward the chuck 552 and the ring member R. Alternatively, instead of the laser light source 820, a light source such as a light-emitting diode (LED) may be provided in the substrate-type sensor device 800.

The camera 830 may capture an image of the interior of the process space 511 in the process chamber 510. The camera 830 may capture an image of an area irradiated by the laser beam from the laser light source 820. The camera 830 may capture an image including the chuck 552 and the ring member R. The camera 830 may transmit the captured image data to the controller 700 via the wireless communication module 840. The wireless communication module 840 may transmit data to the controller 700 using a wireless communication standard such as Wi-Fi.

In order to measure the etch amount of the ring member R, the laser light source 820 of the substrate-type sensor device 800 emits a laser beam to the chuck 552 and the ring member R. In this case, the image including the chuck 552 and the ring member R, captured by the camera 830, is transmitted to the controller 700. The controller 700 may measure the etch amount of the ring member R based on the captured image.

As shown in FIG. 4, the substrate-type sensor device 800 may be moved into the process space 511 in the process chamber 510 while being supported by the robot hand 352 of the transfer robot 350. In the state in which the substrate-type sensor device 800 is spaced apart from the chuck 552 while being supported by the robot hand 352, the laser light source 820 may direct a laser beam toward the chuck 552 and the ring member R, and the camera 830 may capture an image including the chuck 552 and the ring member R. The substrate-type sensor device 800 may transmit the image to the controller 700 via the wireless communication module 840.

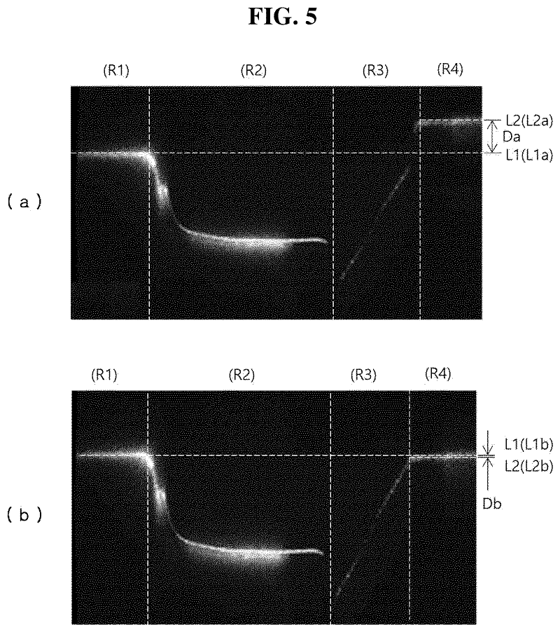

FIG. 5 shows examples of images captured by the camera 830 of the substrate-type sensor device 800 in the substrate processing apparatus according to the present disclosure. FIG. 5(a) shows an example of a first image captured at a first time point, and FIG. 5(b) shows an example of a second image captured at a second time point after the first time point.

The controller 700 may detect an area corresponding to the chuck 552 and an area corresponding to the ring member R in the image, and may compare the shape of the chuck 552 with the shape of the ring member R in the image to measure the etch amount of the ring member R. As shown in FIGS. 5(a) and 5(b), a first area R1 corresponding to the chuck 552, a second area R2 corresponding to a depressed portion in the edge of the chuck 552, a third area R3 corresponding to the boundary surface of the ring member R, and a fourth area R4 corresponding to the upper surface of the ring member R are detected. Each of the areas R1 to R4 may be defined in advance in the image. Alternatively, the controller 700 may detect each of the areas R1 to R4 in the captured image. In the present disclosure, the controller 700 may compare a chuck reference line L1 detected in the first area R1 with a ring reference line L2 detected in the fourth area R4 in the image to measure the etch amount of the ring member R. The chuck reference line L1 and the ring reference line L2 are lines parallel to the horizontal axis of the image. The vertical heights of the chuck reference line L1 and the ring reference line L2 may be defined in the image, and the height of the chuck reference line L1 and the height of the ring reference line L2 may be compared with each other to measure the etch amount of the ring member R.

The controller 700 may detect the chuck reference line L1 corresponding to the surface of the chuck 552 and the ring reference line L2 corresponding to the upper surface of the ring member R in the image, and may compare the position of the chuck reference line L1 with the position of the ring reference line L2 to measure the etch amount of the ring member R. The controller 700 may calculate the difference (L2-L1) between the height of the chuck reference line L1 and the height of the ring reference line L2, and may calculate the etch amount of the ring member R based on the height difference.

The controller 700 may compare the first image captured at the first time point (refer to FIG. 5(a)) with the second image captured after a predetermined time period has elapsed from the first time point or after the process has been performed a predetermined number of times (refer to FIG. 5(b)), thereby measuring the etch amount of the ring member R.

The controller 700 may detect a first chuck reference line L1a corresponding to the surface of the chuck 552 and a first ring reference line L2a corresponding to the upper surface of the ring member R in the first image, and may measure a first distance Da (=L2a-L1a) between the first chuck reference line L1a and the first ring reference line L2a in the first image. The controller 700 may detect a second chuck reference line L1b corresponding to the surface of the chuck 552 and a second ring reference line L2b corresponding to the upper surface of the ring member R in the second image, and may measure a second distance Db (=L2b-L1b) between the second chuck reference line L1b and the second ring reference line L2b in the second image. The controller 700 may measure the etch amount of the ring member R based on the difference (Da−Db) between the first distance Da and the second distance Db. For example, if the first distance Da is 300 μm in the first image and the second distance Db is −10 μm in the second image, it may be confirmed that 310 μm of etching has occurred.

The controller 700 may control the ring lifting device 560 to raise the ring member R when the etch amount of the ring member R exceeds a reference value (e.g., 100 μm). The controller 700 may control the ring lifting device 560 to maintain the height of the ring member R until the etch amount reaches the reference value and to raise the ring member R upon determining that the etch amount exceeds the reference value. The controller 700 may control the ring lifting device 560 to raise the ring member R by a height corresponding to the etch amount of the ring member R. For example, upon determining that 300 μm of etching has occurred in the ring member R, the controller 700 may control the ring lifting device 560 to raise the ring member R by 300 μm.

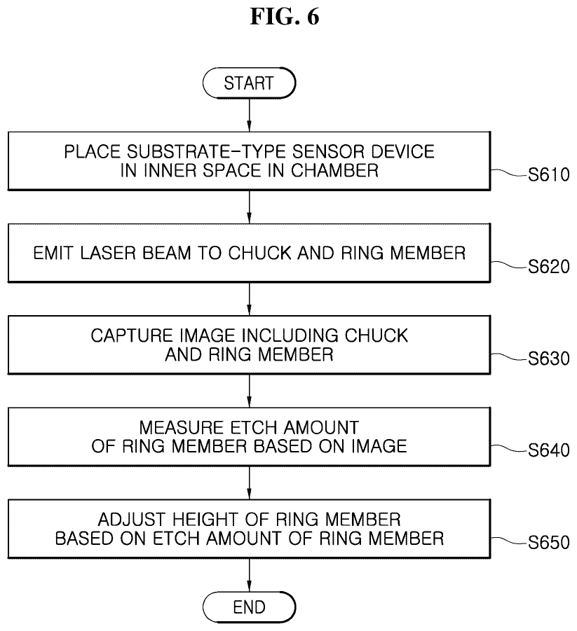

FIG. 6 is a flowchart showing a method of adjusting the height of the ring member R in the substrate processing apparatus according to the present disclosure. As described above, there is provided a method of adjusting the height of the ring member R located around the edge of the chuck 552 that supports the substrate W in the substrate processing apparatus using plasma. The method of adjusting the height of the ring member R includes a step of placing the substrate-type sensor device 800, which has a shape corresponding to the substrate W and is provided with the laser light source 820 and the camera 830, in the process space 511 in the process chamber 510 (S610), a step of emitting, by the laser light source 820, a laser beam to the chuck 552 and the ring member R (S620), a step of capturing, by the camera 830, an image including the chuck 552 and the ring member R (S630), a step of measuring the etch amount of the ring member R based on the image (S640), and a step of adjusting the height of the ring member R based on the etch amount of the ring member R (S650).

In step S610, the substrate-type sensor device 800 is placed in the process space 511 in the process chamber 510. As shown in FIG. 4, the substrate-type sensor device 800 is moved into the process space 511 while being supported by the robot hand 352 of the transfer robot 350.

In step S620, the laser light source 820 emits a laser beam to the chuck 552 and the ring member R. In step S630, the camera 830 captures an image including the chuck 552 and the ring member R. With the substrate-type sensor device 800 being supported by the robot hand 352 and spaced apart from the chuck 552, the laser light source 820 may direct a laser beam toward the chuck 552 and the ring member R, and the camera 830 may capture an image including the chuck 552 and the ring member R.

In step S640, the controller 700 measures the etch amount of the ring member R based on the image. The step of measuring the etch amount of the ring member R based on the image (S640) may include a step of detecting the chuck reference line L1 corresponding to the surface of the chuck 552 in the image, a step of detecting the ring reference line L2 corresponding to the upper surface of the ring member R, and a step of comparing the position of the chuck reference line L1 with the position of the ring reference line L2 to measure the etch amount of the ring member R.

The step of measuring the etch amount of the ring member R (S640) includes a step of comparing the first image captured at the first time point with the second image captured after a predetermined time period has elapsed from the first time point or after the process has been performed a predetermined number of times to measure the etch amount of the ring member R. The step of measuring the etch amount of the ring member R includes a step of detecting the first chuck reference line L1a corresponding to the surface of the chuck 552 and the first ring reference line L2a corresponding to the upper surface of the ring member R in the first image and a step of measuring the first distance Da between the first chuck reference line L1a and the first ring reference line L2a in the first image. The step of measuring the etch amount of the ring member R includes a step of detecting the second chuck reference line L1b corresponding to the surface of the chuck 552 and the second ring reference line L2b corresponding to the upper surface of the ring member R in the second image and a step of measuring the second distance Db between the second chuck reference line L1b and the second ring reference line L2b in the second image. The step of measuring the etch amount of the ring member R includes a step of measuring the etch amount of the ring member R based on the difference (Db-Da) between the first distance Da and the second distance Db.

In step S650, the controller 700 adjusts the height of the ring member R based on the etch amount of the ring member R using the ring lifting device 560. The step of adjusting the height of the ring member R (S650) includes a step of controlling the ring lifting device 560 to raise the ring member R when the etch amount of the ring member R exceeds a reference value.

The step of adjusting the height of the ring member R (S650) includes a step of controlling the ring lifting device 560 to raise the ring member R by a height corresponding to the etch amount of the ring member R.

As is apparent from the above description, according to the present disclosure, since an image including the chuck and the ring member is captured using the substrate-type sensor device and the etch amount of the ring member is measured based on the image, it may be possible to check the etch amount of the ring member without opening the chamber and to appropriately adjust the height of the ring member.

Although the preferred embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the accompanying claims, and all technical ideas within the scope of equivalents to the claims should be construed as falling within the scope of the disclosure.

What is claimed is:

1. A substrate processing apparatus using plasma, the substrate processing apparatus comprising:
a process chamber defining a process space for a substrate;
a chuck located in the process space, the chuck being configured to support the substrate from below;
a ring member located around an edge of the chuck;
a ring lifting device configured to raise and lower the ring member; and
a controller configured to measure an etch amount of the ring member and to adjust a height of the ring member based on the etch amount using the ring lifting device,
wherein a substrate-type sensor device having a shape corresponding to the substrate and comprising a laser light source and a camera is located in the process space,
wherein the laser light source emits a laser beam to the chuck and the ring member,
wherein the camera captures an image including the chuck and the ring member and transmits the image to the controller, and
wherein the controller measures the etch amount of the ring member based on the image.

2. The substrate processing apparatus as claimed in claim 1, wherein the substrate-type sensor device is moved into the process space while being supported by a robot hand of a transfer robot, and
wherein, with the substrate-type sensor device being supported by the robot hand and spaced apart from the chuck, the laser light source directs the laser beam toward the chuck and the ring member, and the camera captures the image.

3. The substrate processing apparatus as claimed in claim 1, wherein the substrate-type sensor device transmits the image to the controller via a wireless communication module.

4. The substrate processing apparatus as claimed in claim 1, wherein the controller is configured to:
detect a chuck reference line corresponding to a surface of the chuck in the image;
detect a ring reference line corresponding to an upper surface of the ring member; and
compare a position of the chuck reference line with a position of the ring reference line to measure the etch amount of the ring member.

5. The substrate processing apparatus as claimed in claim 1, wherein the controller compares a first image captured at a first time point with a second image captured after a predetermined time period has elapsed from the first time point or after a process has been performed a predetermined number of times to measure the etch amount of the ring member.

6. The substrate processing apparatus as claimed in claim 5, wherein the controller is configured to:
detect a first chuck reference line corresponding to a surface of the chuck and a first ring reference line corresponding to an upper surface of the ring member in the first image; and
measure a first distance between the first chuck reference line and the first ring reference line in the first image.

7. The substrate processing apparatus as claimed in claim 6, wherein the controller is configured to:
detect a second chuck reference line corresponding to the surface of the chuck and a second ring reference line corresponding to the upper surface of the ring member in the second image; and
measure a second distance between the second chuck reference line and the second ring reference line in the second image.

8. The substrate processing apparatus as claimed in claim 7, wherein the controller measures the etch amount of the ring member based on a difference between the first distance and the second distance.

9. The substrate processing apparatus as claimed in claim 1, wherein the controller controls the ring lifting device to raise the ring member when the etch amount of the ring member exceeds a reference value.

10. The substrate processing apparatus as claimed in claim 1, wherein the controller controls the ring lifting device to raise the ring member by a height corresponding to the etch amount of the ring member.

11. A method of adjusting a height of a ring member located around an edge of a chuck supporting a substrate in a substrate processing apparatus using plasma, the method comprising:
placing a substrate-type sensor device, having a shape corresponding to the substrate and comprising a laser light source and a camera, in a process space in a process chamber;
emitting, by the laser light source, a laser beam to the chuck and the ring member;
capturing, by the camera, an image including the chuck and the ring member;
measuring an etch amount of the ring member based on the image; and
adjusting a height of the ring member based on the etch amount of the ring member.

12. The method as claimed in claim 11, wherein the substrate-type sensor device is moved into the process space while being supported by a robot hand of a transfer robot, and
wherein, with the substrate-type sensor device being supported by the robot hand and spaced apart from the chuck, the laser light source directs the laser beam toward the chuck and the ring member, and the camera captures the image.

13. The method as claimed in claim 11, wherein measuring the etch amount of the ring member based on the image comprises:
detecting a chuck reference line corresponding to a surface of the chuck in the image;
detecting a ring reference line corresponding to an upper surface of the ring member; and
comparing a position of the chuck reference line with a position of the ring reference line to measure the etch amount of the ring member.

14. The method as claimed in claim 11, wherein measuring the etch amount of the ring member comprises comparing a first image captured at a first time point with a second image captured after a predetermined time period has elapsed from the first time point or after a process has been performed a predetermined number of times to measure the etch amount of the ring member.

15. The method as claimed in claim 14, wherein measuring the etch amount of the ring member comprises:
detecting a first chuck reference line corresponding to a surface of the chuck and a first ring reference line corresponding to an upper surface of the ring member in the first image; and
measuring a first distance between the first chuck reference line and the first ring reference line in the first image.

16. The method as claimed in claim 15, wherein measuring the etch amount of the ring member comprises:
detecting a second chuck reference line corresponding to the surface of the chuck and a second ring reference line corresponding to the upper surface of the ring member in the second image; and
measuring a second distance between the second chuck reference line and the second ring reference line in the second image.

17. The method as claimed in claim 16, wherein measuring the etch amount of the ring member comprises measuring the etch amount of the ring member based on a difference between the first distance and the second distance.

18. The method as claimed in claim 11, wherein adjusting the height of the ring member comprises controlling a ring lifting device to raise the ring member when the etch amount of the ring member exceeds a reference value.

19. The method as claimed in claim 11, wherein adjusting the height of the ring member comprises controlling a ring lifting device to raise the ring member by a height corresponding to the etch amount of the ring member.

20. A substrate processing apparatus using plasma, the substrate processing apparatus comprising:
a process chamber defining a process space for a substrate;
a transfer robot comprising a robot hand configured to transfer the substrate to the process space;
a chuck located in the process space, the chuck being configured to support the substrate from below;
a ring member located around an edge of the chuck;
a ring lifting device configured to raise and lower the ring member; and
a controller configured to measure an etch amount of the ring member and to adjust a height of the ring member based on the etch amount using the ring lifting device,
wherein a substrate-type sensor device having a shape corresponding to the substrate and comprising a laser light source and a camera is located in the process space while being supported by the robot hand,
wherein, with the substrate-type sensor device being supported by the robot hand and spaced apart from the chuck, the laser light source emits a laser beam to the chuck and the ring member,
wherein the camera captures an image including the chuck and the ring member and transmits the image to the controller, and
wherein the controller compares a first image captured at a first time point with a second image captured after a predetermined time period has elapsed from the first time point or after a process has been performed a predetermined number of times to measure the etch amount of the ring member.
